(19) United States
(12) Patent Application Publication
(10) Pub. No.: US 2025/0113650 A1
(43) Pub. Date: Apr. 3, 2025

(54) WAVEGUIDE-BASED SINGLE-PHOTON AVALANCHE DIODE (SPAD)

(71) Applicant: ADVANCED MICRO FOUNDRY PTE. LTD., Singapore (SG)

(72) Inventors: Yanikgonul SALIH, Singapore (SG); Xianshu LUO, Singapore (SG)

(73) Assignee: ADVANCED MICRO FOUNDRY PTE. LTD., Singapore (SG)

(21) Appl. No.: 18/728,938

(22) PCT Filed: Mar. 1, 2022
(86) PCT No.: PCT/SG2022/050101

§ 371 Date: Jul. 15, 2024

(51) Int. Cl. H10F 77/20; H10F 30/225; H10F 77/40

(52) U.S. Cl. CPC H10F 77/206; H10F 30/225; H10F 77/413

(57) ABSTRACT

The present disclosure relates generally to a single photon avalanche diode (SPAD) having a rib waveguide with a doping profile having a multiplication junction, a top cladding layer disposed on a top surface of the rib waveguide, a bottom cladding layer disposed on a bottom surface of the rib waveguide. The SPAD has an anode, a cathode and two field plates. The anode, cathode and the two field plates are configured to suppress the electric field over the multiplication junction relative to a SPAD without the at least two field plates, and the two field plates and/or cathode are positioned adjacent to the intersection of the multiplication junction and the top cladding layer.

### TECHNICAL FIELD

The present disclosure relates to a field of silicon photonic and single-photon avalanche diodes (SPAD), and more particularly to a waveguide-based SPAD.

### BACKGROUND

FIG. 1 illustrates a conventional waveguide-based SPAD. This waveguide-based SPAD includes a p-n⁺ junction diode defined in a silicon rib waveguide. As illustrated, a rib waveguide with an asymmetric etch depth is provided to improve charge carrier collection efficiency by reducing sidewall collisions. The rib waveguide width and length account for near-unity absorption for operation in the visible band. This waveguide-based SPAD is cladded with SiO₂ from top and bottom. The anode and cathode are placed symmetrically with respect to the center of the rib waveguide. Further, visible photons are end-fired or evanescently coupled from a Silicon Nitride (SiN) channel waveguide to Si waveguide-based SPAD. Further, the photogenerated charge carriers are laterally swept across the high-field depletion region. Generally, electrons have higher impact ionization coefficient than holes in Silicon. Thus, electrons need to undergo impact ionization process rather than holes to achieve high multiplication gains. By heavily doping n-side of the p-n+ junction, the depletion region is formed mostly in the p-region, where electrons are the minority carriers. The depletion region is mostly formed at the waveguide core such that photogenerated electron-hole pairs can be effectively separated and swept across the high field depletion region.

Single-photon avalanche diodes SPADs are photodetectors operating in a reverse bias voltage (V_{B}) that is slightly beyond their avalanche breakdown voltage (V_{br}). In a SPAD operation, an incident single photon can trigger an avalanche of secondary charge carrier generation via impact ionization process, and eventually the device provides a measurable electrical signal. Recent studies to achieve Geiger-mode operation with waveguide-integrated avalanche photodiodes APDs report on premature surface breakdown and a subsequent breakdown voltage walk-out due to charge carrier injection and trapping at the Si/SiO₂ interface. This is evidenced by the fact that the breakdown voltage V_{br} walks out to higher values upon successive avalanche breakdowns as more and more hot carriers are injected and subsequently trapped at the trap states found in the Si/SiO₂ interface.

The APD multiplication gain heavily depends on the electric field strength inside the depletion region, which can reach up to 1 MV/cm in the Geiger-mode operation. However, this strong electric field can get weaker due to screening of charge carriers that are trapped in the proximity of the depletion region; this eventually lowers the field-dependent multiplication gain.

Forming a guard ring (GR) around a depletion region can prevent premature edge breakdown and subsequent charge trapping effects; thus, it is widely employed in normal-incident APDs fabricated in various CMOS technologies. However, the conventional ion implantation and ion diffusion steps to form a GR structure impose stringent process control for waveguide-based SPADs of submicron dimensions as retaining a well-defined doped region in such small geometries is challenging due to dopant diffusion problem. Moreover, some GR structures such as shallow trench isolations can further introduce interface trap centres if they are not properly surface-passivated. This consequently degrades various performance metrics of Geiger-mode APDs such as dark count rate and afterpulsing probability.

An alternative approach for engineering electric field inside semiconductor devices utilizes electric field plates adjacent to the device. For instance, such field plates have been shown to improve the breakdown resilience of the gate/drain junction of the high-electron mobility transistors (HEMT) used in power electronics. However, this type of in-situ control of electric field strength has yet to be implemented for waveguide-based APD devices, whose operation relies on very high electric field but is prone to the premature surface breakdown.

Thus, there remains a need for a system to eliminate premature surface breakdown and its associated secondary effects to achieve Geiger-mode operation of silicon waveguide-based APDs for single photon detection.

### SUMMARY

The following summary is provided to facilitate an understanding of some of the innovative features unique to the disclosed embodiment and is not intended to be a full description. A full appreciation of the various aspects of the embodiments disclosed herein can be gained by taking into consideration the entire specification, claims, drawings, and abstract as a whole.

In a first aspect of present disclosure, there is provided a single photon avalanche diode (SPAD) comprising a rib waveguide with a doping profile comprising a multiplication junction, a top cladding layer disposed on a top surface of the rib waveguide, a bottom cladding layer disposed on a bottom surface of the rib waveguide. Further, the SPAD comprises an anode, a cathode and at least two field plates. The anode, cathode and the at least two field plates are configured to suppress the electric field over the multiplication junction relative to a SPAD without the at least two field plates, and the two field plates are positioned adjacent to the intersection of the multiplication junction.

In one embodiment, the single photon avalanche diode of claim 1, wherein the doping profile is selected from p+/i/p/n+, p++/p/i/n+/n++, and p++/p/n+/n++.

In one embodiment, the single photon avalanche diode having the multiplication junction is i/n+ or p/n+.

In one embodiment, the multiplication junction forms a multiplication region when an appropriate bias voltage is applied between the anode and cathode.

In one embodiment, the diode is reverse-biased slightly beyond the avalanche breakdown voltage of the diode to achieve Geiger-mode operation, wherein the anode is kept at lower electric potential than the cathode, wherein the cathode is electrically grounded.

In another embodiment, the at least two field plates comprise a first field plate and a second field plate that sandwich the rib waveguide adjacent to the multiplication junction, and they are voltage biased.

In one embodiment, the anode is disposed at a first end of the rib waveguide and extends vertically to form an anode pillar, the cathode is disposed at a second end of the rib waveguide and extends vertically to form a cathode pillar. The at least two field plates comprise a first field plate and a second field plate that are positioned adjacent to the multiplication junction. The first field plate is formed in the top cladding layer, and the second field plate is formed in the bottom cladding layer.

In one embodiment, the first field plate is asymmetrically positioned between the anode pillar and the cathode pillar, and it is voltage biased.

In one embodiment, the doping profile of the rib waveguide is p++/p/n+/n++ and the multiplication junction is p/n+, wherein the first field plate is horizontally displaced from the p-n junction by a distance Δx over the n+ doped region and vertically displaced from the n+ doped region by a distance d1. The second field plate is in vertical alignment with the first field plate and is horizontally displaced from the p-n junction by a distance Δx underneath the n+ doped region and vertically displaced from the n+ doped region by a distance d2.

In another embodiment, a potential difference of V_{B} with respect to an electrical ground is applied to the first field plate and a second field plate to suppress the electrostatic potential gradient in the y-axis (i.e., E_{y}) along the interface between the multiplication junction and the top cladding layer to improve the resilience of the diode to premature surface breakdown.

In one embodiment, the at least two field plates comprise a first field plate and a second field plate, the first field plate with the anode forms an L-shaped extended anode and the second field plate with the cathode forms an L-shaped extended cathode both of which extend towards the multiplication junction through the top cladding layer. The L-shaped extended anode and L-shaped extended cathode suppress the electrostatic potential gradient along the y-axis (i.e., E_{y}) along the interface between the multiplication junction and the top cladding layer to improve the resilience of the diode to premature surface breakdown.

In another embodiment, the first field plate laterally extends towards the multiplication junction in the second metal layer of the top cladding layer. The second field plate laterally extends towards the multiplication junction in the first metal layer of the top cladding layer,

In one embodiment, the first field plate and the second field plate are horizontally separated by a gap g.

In one embodiment, the second field plate laterally extends towards the multiplication junction in the first metal layer with a distance Δx in between.

In another embodiment, the doping profile of the rib waveguide is p++/p/n+/n++ and the multiplication junction is p/n+. The second field plate extends from the n++ doped region to the n+ doped region and is vertically displaced from the n+ doped region by a distance d₄. The first field plate is horizontally displaced from the second field plate by a gap g and is vertically displaced from the p doped region by a distance d₃.

In one embodiment, the first field plate is extended in the second metal layer instead of in the first metal layer as in the second field plate so as to prevent disturbance of the field suppression over the n+ doped region by the second field plate and to avoid dielectric breakdown between the field plates while maintaining adequate electric field suppression along the intersection of the p doped region and the top cladding layer.

### BRIEF DESCRIPTION OF THE DRAWINGS

Other objects, features, and advantages of the embodiment will be apparent from the following description when read with reference to the accompanying drawings. In the drawings, wherein like reference numerals denote corresponding parts throughout the several views:

The diagrams are for illustration only, which thus is not a limitation of the present disclosure, and wherein:

FIG. 1 illustrates a waveguide-based single photon avalanche diode (SPAD) according to a prior art;

FIG. 2 illustrates a cross-sectional view of a waveguide-based SPAD, in accordance with an aspect of the present disclosure;

FIG. 3 illustrates a cross-sectional view of a waveguide-based SPAD, in accordance with another aspect of the present disclosure;

FIG. 4 shows a graph of simulated data illustrating the suppression of electrical field in the top cladding layer between waveguides of the prior art (Ref), the waveguide-based SPAD of FIG. 2 (SFP with Δx=0 nm) and FIG. 3 (EFP with Δx=0 nm), in accordance with an aspect of the present disclosure;

FIG. 5 shows a graph illustrating the suppression of electrical field in the bottom cladding layer (a.k.a. buried oxide layer) between waveguide of the prior art (Ref), the waveguide-based SPAD of FIG. 2 (SFP with Δx=0 nm) and FIG. 3 (EFP with Δx=0 nm), in accordance with an aspect of the present disclosure;

FIG. 6 shows a graph illustrating the simulated electric field profiles of the waveguide of the prior art (Ref), the waveguide-based SPAD of FIG. 2 (SFP with Δx=0 nm) and FIG. 3 (EFP with Δx=0 nm), in accordance with an aspect of the present disclosure.

FIG. 7 illustrates a graph of simulated dark-current vs reverse bias voltage for the waveguide-based SPAD of the prior art (Ref), the waveguide-based SPAD of FIG. 2 (SFP with Δx=0 nm) and FIG. 3 (EFP with Δx=0 nm), in accordance with an aspect of the present disclosure,

### DETAILED DESCRIPTION OF ILLUSTRATIVE EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

Throughout the prior art, there remains a need for a system to eliminate the premature surface breakdown and its associated secondary effects for achieving Geiger-mode operation of silicon waveguide-based APDs for single-photon detection.

Accordingly, there is provided a single photon avalanche diode (SPAD) disclosed herein that provides a solution to the premature surface breakdown through the inclusion of field-modulating plates, also termed herein as field plates (FPs). Specifically, the FPs can be located near the intersection of the multiplication region of the waveguide and cladding layers, which can be highly defective. These FPs can act to reduce the electric field along the oxide interface, and hence they can significantly reduce the oxide injection current. Thus, the hot carrier injection and trapping at the oxide interface, and the breakdown voltage walk-out thereof, is mitigated.

The geometry and positioning of the FPs can be configured in any way that the electric field strength along the oxide interface is reduced compared to a SPAD without any FPs. In particular, the FPs geometry and positioning in cooperation with the anode and cathode can suppress the electric field over the multiplication junction of the waveguide.

The single photon avalanche diode (SPAD) disclosed herein can require no additional doping and provide precise and in-situ control of electric field strength along the oxide interface, hence the approach may be applicable to other devices operating in high electric fields.

In one embodiment, the FPs can be formed outside the SPAD active region and optical absorption region, which does not affect the quantum efficiency of the diode. The exemplified FP designs and SPADs disclosed herein can be compatible with conventional CMOS fabrication steps and require only the optional back-metallization step.

Accordingly, in one embodiment, there is provided a SPAD that can comprise a rib waveguide with a doping profile comprising a multiplication junction; a top cladding layer deposited on a top surface of the rib waveguide; a bottom cladding layer located on a bottom surface of the rib waveguide; an anode; a cathode; and at least two field plates, wherein the anode, cathode and at least two field plates can be configured to suppress the electric field over the multiplication junction relative to a SPAD without the at least two field plates, wherein the at least two field plates and/or cathode can be positioned adjacent to the intersection of the multiplication junction and the top cladding layer.

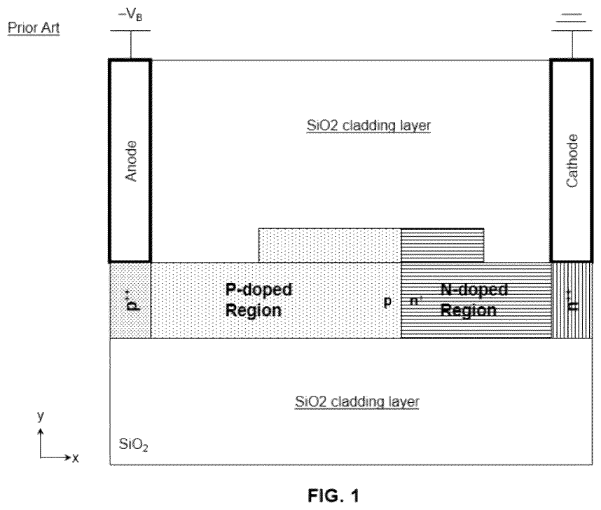

In one embodiment, the rib waveguide can be a Si rib waveguide. The rib waveguide can have a thickness of about 340 nm including an asymmetric etch depth of about 90 nm and a width of about 900 nm. The etching depth can create a rib waveguide structure with p- and n-doped regions defined in both rib and slab portions of the waveguide, as shown in FIGS. 1, 2 and 3.

In one embodiment, the rib waveguide can have a length that accounts for near-unity absorption (e.g., ˜16 μm at about 640 nm) for operation in the visible band. In one embodiment, the length of the APD/SPAD device can be shorter or longer depending on the operation wavelength. A silicon APD/SPAD device can be used for detecting light of whichwavelength is shorter than ˜1.1 μm. Considering the commonly used near-IR wavelengths of 850 and 905 nm (which are used for short-reach data communication and LIDAR applications, respectively), the device length can be up to 200 μm to account for light absorption of up to 90%. For the absorption of blue light, a 5-μm long device can provide near unity absorption. Accordingly, the rib waveguide length can vary from 5 μm up to 200 μm depending on the operating wavelength.

In one embodiment, the device thickness can be constrained by the foundry to manufacture the devices. The thicker Si device layer with an asymmetric etch depth can be favourable to reduce the side-wall collisions of hot carriers and associated charge trapping effects along the oxide interface. Accordingly, the rib waveguide can have a thickness of 340 nm up to 500 nm.

In one embodiment, the device width can be varied to an extent that it does not considerably excite higher order modes inside the Si waveguide. In particular, the device width can be up to 1 μm.

In one embodiment, the doping profile of the rib waveguide can include one or more doped P-regions, one or more doped N-regions and optionally an intrinsic region. In one embodiment, the doping profile can include a combination of regions selected from a heavily doped P-region (p++), a moderately doped P-region (p+), a lightly doped P-region (p), an Intrinsic region, a lightly doped N-region (n), a moderately doped N-region (n+), and a heavily doped N-region (n++). The terms ‘lightly doped’, ‘moderately doped’, ‘heavily doped’ and the like are principally used in relative terms but should otherwise be interpreted in the context of standard features of commercial CMOS fabrication processes.

The rib waveguide can be doped using a suitable dopant to form the desired doping profile. Specifically, the rib waveguide can be doped using dopants such as, but not limited to, boron, gallium, and the like to form the P-doped region. Further, the rib waveguide can be doped using dopants such as, but not limited to, arsenic, phosphorus, and the like to form the N-doped region.

The doping profile of the rib waveguide can be engineered so that the multiplication junction forms a SPAD multiplication region when an appropriate bias voltage is applied between the contacts. In one embodiment, the multiplication junction forms a multiplication region when an appropriate bias voltage is applied between the anode and cathode.

In one embodiment, the doping profile can be p+/i/p/n+ or p++/p/i/n+/n++ and the multiplication junction can be either p/n+ or i/n+, respectively. In one embodiment, the doping profile can be p++/p/n+/n++ and the multiplication junction can be p/n+.

The SPAD disclosed herein can comprise a silicon rib waveguide with a p/n+ junction defined inside the waveguide core, and it can be coupled to a silicon nitride (SiN) channel waveguide for coupling of visible/near-infrared light into the SPAD.

In one embodiment, the SPAD can be reverse-biased beyond the avalanche breakdown voltage of the SPAD to achieve Geiger-mode operation, wherein the anode can be kept at lower electric potential than the cathode which is electrically grounded.

In one embodiment, the anode is an electrode through which the conventional current enters into a polarized electrical device. The cathode is an electrode through which conventional current leaves an electrical device. The anode can be positioned at a first end of the rib waveguide and contacted above a p-doped region. The anode can be biased to a voltage −V_{B} that is slightly more negative than the negated breakdown voltage (i.e., −V_{B}<−V_{br}) of the waveguide-based SPAD.

In one embodiment, the cathode can be positioned at a second end of the rib waveguide and contacted above an n-doped region. The cathode can be connected to the electrical ground.

In one embodiment, the anode can be positioned at a first end of the rib waveguide and extend vertically to form an anode pillar, and the cathode can be positioned at a second end of the rib waveguide and extend vertically to form a cathode pillar.

In one embodiment, the doping profile of the rib waveguide can be p++/p/n+/n++ with the anode contacted with the p++ doped region and the cathode contacted with the n++ doped region.

In one embodiment, the anode can be kept at a lower electric potential than the cathode, and the cathode is electrically grounded (i.e., −V_{B}<0 V).

In one embodiment, the anode and cathode can be placed symmetrically with a distance between them of about 3 μm. As will be appreciated by those skilled in the art, the distance between the anode and cathode can vary and be subject to the foundry manufacturing rules. In one embodiment, the anode and cathode can be placed symmetrically with a distance between them of about 2 μm to 5 μm.

In one embodiment, the anode and cathode can be made from common metals used in CMOS process such as aluminium and copper.

In one embodiment, the top and bottom cladding layer refer to the claddings above and below the rib waveguide, respectively. The top and bottom cladding layers can be made up of Silicon Dioxide (SiO₂) material. The SiO₂ material is a good dielectric material thus, the SiO₂ material can provide a better insulation in the waveguide-based SPAD.

In one embodiment, the top cladding layer can have a thickness of about 1 to 3 μm. In one embodiment, the bottom cladding layer can have a thickness of about 1 to 3 μm.

The silicon oxide can be deposited on the top surface of the rib waveguide as the top cladding layer and provided to insulate the anode, the cathode, and a conducting channel of the waveguide-based SPAD.

In one embodiment, a substrate layer can be disposed underneath the bottom cladding layer. The substrate layer can be made up of a material such as, but not limited to, silicon (Si). The substrate layer can be partially etched and metallized to allow for electric field suppression along the bottom oxide interface of the SPAD multiplication region. In one embodiment, the substrate layer can be a conductive substrate layer via back-metallization process.

In one embodiment, a distance (d₂) between the substrate layer and the bottom cladding layer can be in a range from about 500 nm to about 1 μm.

In one embodiment, the at least two field plates can comprise a first FP and a second FP that configured such that the electric field strength along the oxide interface is reduced compared to the absence of the FPs (e.g., FIG. 1). In particular, the geometry and positioning of the at least two field plates can cooperate with the anode and cathode to suppress the electric field over the multiplication junction of the waveguide.

In one embodiment, one of the at least two field plates can be horizontally separated or displaced from the vertical axis or plane of the multiplication junction by a distance Δx. In one embodiment, the distance Δx can be about 0 nm. In one embodiment, the distance Δx can be within ±100 nm.

In one embodiment, the at least two field plates can be positioned asymmetrically to be more on one side of the multiplication junction as the field strength there is higher. In one embodiment, the at least two field plates can be positioned to suppress the electric field strength along the oxide interface over the multiplication region. For example, the at least two field plates can be positioned adjacent to a p/n+ junction, where the multiplication and absorption regions partially overlap, and more specifically they can be positioned on the n+ doped side.

The at least two field plates can be made up of a material such as, but not limited to, aluminium or copper, and the like.

### Sandwich Field Plates (SFP) Configuration

In one embodiment, the at least two field plates can be recessed and biased field plates sandwiching the rib waveguide SPAD. Accordingly, this configuration of the field plates can be termed as Sandwich Field Plates (SFP).

In one embodiment of the SFP, the at least two field plates can comprise a first FP and a second FP that sandwich the rib waveguide adjacent to the multiplication junction and can be electrically biased by a voltage source.

In one embodiment of the SFP, the first FP can be formed inside the top cladding layer, and the second FP can be formed inside the bottom cladding layer.

In one embodiment of the SFP, the first FP can be asymmetrically positioned between the anode and the cathode.

In one embodiment of the SFP, the doping profile of the rib waveguide can be p++/p/n+/n++ and the multiplication junction p/n+, wherein the first FP can be horizontally displaced from the multiplication junction by a distance Δx over the n+ doped region and vertically displaced from the n+ doped slab region by a distance d₁, and the second FP can be in vertical alignment with the first FP and is horizontally displaced from the multiplication junction by a distance Δx underneath the n+ doped region and vertically displaced from the n+ doped slab region by a distance d₂. In particular, Δx refers to the distance between the p-n junction and the left edge of the FP located in the right-hand side (RHS) of the device.

In one embodiment of the SFP, the distance d₁ can range from about 500 nm to 1 μm. In one embodiment, the distance d₁ can be about 500 nm.

In one embodiment of the SFP, the distance d₂ can range from about 500 nm to 1 μm. In one embodiment, the distance d₂ can be about 500 nm.

In one embodiment of the SFP, a potential difference of V_{B} with respect to an electrical ground can be applied to the first FP and the second FP to suppress the electrostatic potential gradient along the y-axis (i.e., E_{y}) along the interface between the multiplication junction and the cladding layers to improve the resilience of the diode to premature surface breakdown.

The biased field plate configuration of the SFP can be manufactured via an additional back-metallization process for user-controlled oxide field suppression. In one embodiment, the second FP can be formed by a back-metallization process.

In one embodiment, the SFP can be manufactured beginning with an SOI wafer followed by etching and ion implantation steps of the Si device layer. Thereafter the Si SPAD comprising a doped Si rib waveguide can be formed and cladded with silicon oxide atop as the first interlayer dielectric. Prior to the metallization steps, the handling wafer can be selectively etched near the p-n junction. Thereafter, the metal layer can be deposited to form the anode and cathode following the etch of the top oxide cladding near the heavily doped p++ and n++ doped regions. The top oxide layer can be selectively etched with a mask set to form the top field plate. Likewise, the bottom field plate is formed via back-metallization process, and finally the bond pad open steps are performed over the oxide-cladded electrodes for electrical contact formation.

In particular, the first and second FPs can be fabricated to be in proximity of the moderately doped region of the p-n+ junction (i.e., n+ doped region), where the electric field strength at the oxide interface is higher.

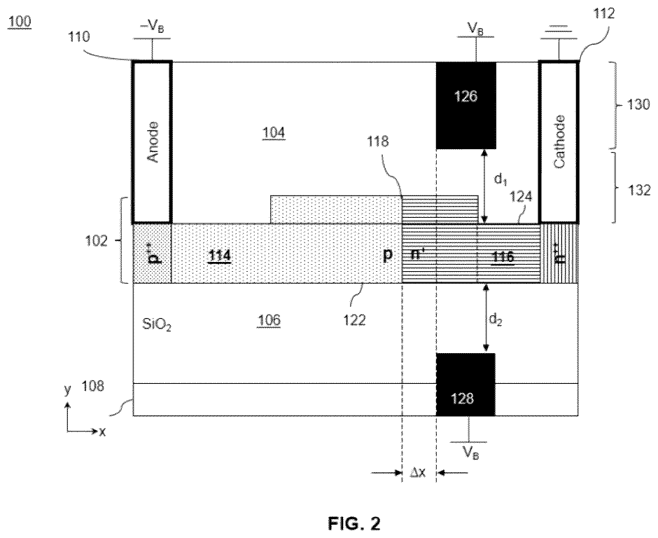

FIG. 2 illustrates an exemplary embodiment of a single photon avalanche diode (SPAD) 100 configured with Sandwich Field Plates, whereby the waveguide has a doping profile of p++/p/n+/n++ with a multiplication junction of p/n+.

The waveguide-based SPAD 100 includes a first FP 126 formed over and adjacent to the n+-doped region 116 and horizontally displaced from the p-n+ junction 118 by a distance Δx. Specifically, the first FP 126 is positioned asymmetrically between the anode 110 and the cathode 112 such that the first FP 126 is adjacent to the n+ doped region 116.

The first FP 126 is formed in a second metal layer 130 of the top cladding layer 104, as opposed to a first metal layer 132 that contains only a portion of the anode and cathode. Further, the first FP 126 is formed at a distance (d₁) from the n+-doped silicon slab region 124. Specifically, the distance (d₁) between the first FP 126 and the n+-doped silicon slab region 124 can be in a range from about 0.5 μm to about 1 μm.

The second FP 128 is formed in the bottom cladding layer 106 and is in the same vertical plane and in alignment with the first FP 126. The second FP 128 spans the entire height of the substrate layer 108 and extends into the bottom cladding layer 106. The second FP 128 is formed at a distance (d₂) from the n+-doped silicon slab region 124. Specifically, the distance (d₂) between the first FP 126 and the n+-doped silicon slab region 124 can be in a range from about 0.5 μm to about 1 μm.

The first FP 126 and the second FP 128 are formed by way of a two-step metallization process. The first FP 126 and the second FP 128 sandwich the rib waveguide and facilitate to reduce the electric field strength along the silicon/oxide interface (i.e., the interface of the rib waveguide 102 with the top cladding layer 104, and the interface of the rib waveguide 102 with the bottom cladding layer 106).

The sandwiching of the rib waveguide by way of the first FP 126 and the second FP 128 can increase the breakdown voltage of the p/n+ junction as the high electric field is pushed from the rib waveguide edges towards the SPAD core. Further, the sandwiching by way of the first FP 126 and the second FP 128 can distribute the electric field lines more homogeneously inside the depletion region such that a more centralized impact generation region is formed inside the waveguide core.

The first FP 126 and the second FP 128 can be biased to a voltage that is of the same magnitude as the voltage applied to the anode with respect to the ground (i.e., −V_{B}) but with opposite polarity (i.e., V_{B}). Specifically, the first FP 126 and the second FP 128 can be voltage biased by a positive voltage V_{B} to reduce the gradient of the electrostatic potential along the y-axis (i.e., the vector component of the electric field along the y-axis, E_{y}) at the intersection of the p/n+ junction and the cladding layer (e.g., the top cladding layer 104 and the bottom cladding layer 106) interface.

### Extended Field Plates (EFP) Configuration

In one embodiment, the at least two field plates can be configured by optimizing the anode and cathode footprint. The at least two field plates can extend the cathode/anode towards the multiplication junction to suppress the electric field strength along the silicon/oxide interface. Accordingly, this configuration of the field plates and modification of the anode and cathode can be termed as Extended Field Plates (EFP).

Thus, the SPAD disclosed herein can employ field plates formed by optimizing the anode/cathode footprint in a two-layer metallization process to improve the resilience of SPAD to premature surface breakdown.

In one embodiment of the EFP, the at least two field plates can comprise a first FP and a second FP.

The first FP is formed by optimizing the anode footprint in a way that it extends towards the multiplication junction in the second metal layer. Likewise, the second FP is formed by designing the cathode footprint such that it extends towards the multiplication junction in the first metal layer. In this regard, the extended anode and extended cathode can suppress the electrostatic potential gradient along the y-axis (i.e., E_{y}) along the interface between the multiplication junction and the top cladding layer to improve the resilience of the diode to premature surface breakdown.

In one embodiment of the EFP, the extended anode and the extended cathode can be separated by a gap g, which can be in the range of about 300 nm to 500 nm, and preferably about 300 nm. As will be appreciated, a smaller gap g would increase the electric field strength between extended FPs and may cause dielectric breakdown of the top cladding layer for high bias voltages, whereas a larger gap g would decrease the effect of extended anode over the p-doped region for a fixed position of the extended cathode.

In one embodiment of the EFP, the extended anode and extended cathode can be formed in an L-shape. The L-shaped extended anode and L-shaped extended cathode can serve as the first and second field plates, respectively. In this regard, the first field plate and the anode can form the same structure. Likewise, the second field plate and the cathode can form the same structure.

In one embodiment of the EFP, the L-shaped cathode can horizontally extend towards the multiplication junction in the first metal layer with a distance Δx there between, and the L-shaped anode can laterally extend towards the multiplication junction in the second metal layer with a distance of g−Δx to said multiplication junction.

In one embodiment of the EFP, the doping profile of the rib waveguide can be p++/p/n+/n++ and the multiplication junction is p/n+. Accordingly, the L-shaped cathode can extend from the n++ doped region to the n+ doped region and can be vertically displaced from the n+ doped silicon slab region by a distance d₄. Further, the L-shaped first FP can extend from the p++ doped region to the p-doped region and is spaced from the L-shaped cathode by a distance g and is vertically displaced from the p doped region by a distance d₃.

In one embodiment of the EFP, the distance d₃ can be in the range of about 1 μm to 1.5 μm, and preferably about 1 μm. As will be appreciated, the larger the distance d₃ would reduce the induced electric field on top of the p-doped rib waveguide section for a given bias voltage V_{B}.

In one embodiment of the EFP, the distance d₄ can be in the range of about 0.5 μm to 0.75 μm, and preferably about 0.5 μm. As will be appreciated, a longer distance d₄ will reduce the effect of electric field suppression over the n-doped rib waveguide section for a given bias voltage V_{B}.

In one embodiment of the EFP, the bottom cladding layer can have a thickness d₅. This distance d₅ is also the distance that separates the bottom surface of the waveguide from the substrate layer. In one embodiment of the EFP, the distance d₅ can be about 0.7 μm to 3 μm.

In one embodiment of the EFP, the first FP can be extended in the second metal layer to prevent enhancement of the electric field over the n+ doped region and any dielectric breakdown between the extended anode and extended cathode while maintaining adequate electric field suppression along the intersection of the p doped region and the top cladding layer.

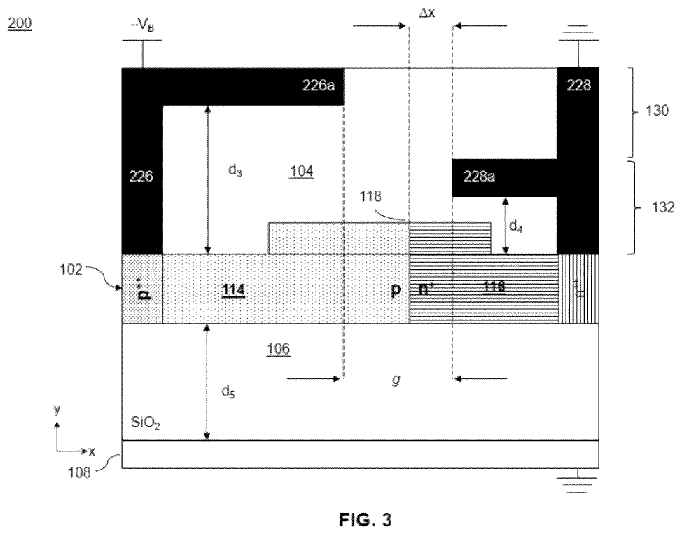

FIG. 3 illustrates an exemplary embodiment of a single photon avalanche diode (SPAD) 200 configured with Extended Field Plates, whereby the waveguide 102 has a doping profile of p++/p/n+/n++ with a multiplication junction 118 of p/n+.

The waveguide-based SPAD 200 includes an L-shaped extended anode 226, 226a and L-shaped extended cathode 228, 228a, which also serve as the first and second field plates, respectively. The extended field plates are formed by forming the anode and cathode footprint in L-shape. Both L-shaped extended field plates are comprised within the first metal layer 132 and the second metal layer 130 of the top cladding layer 104.

The waveguide-based SPAD 200 is designed and configured to optimize the footprints of the anode and the cathode in different metal layers to reduce the electric field strength along the oxide interface. It would be noted that the anode and first field plate 226, 226a in combination form the extended anode, and the cathode and the second field plate 228, 228a in combination form the extended cathode.

The first FP 226 is formed by extending the anode on top of the doped p++ region. Specifically, the first FP 226 forms an L-shaped extended anode of which horizontal portion 226a extends towards the multiplication junction 118 of p/n+ through the top cladding layer 104. Further, the horizontal portion 226a is formed at a distance (d₃) from the p-doped silicon slab region 114.

The second FP 228 is formed by extending the cathode on top of the doped n++ region. Specifically, the second FP 228 forms an L-shaped extended cathode of which horizontal portion 228a extends towards the multiplication junction 118 of p/n+ through the top cladding layer 104 such that the distance between the multiplication junction 118 and the horizontal portion 228a is equal to Δx. Since the electric field strength along the interface between the p/n+ junction and the top cladding layer 104 is highest in the n-doped region 116, the horizontal portion of the second FP 228a is positioned closer to this region compared to the horizontal portion of the first FP 226a to have better field suppression. The horizontal portion 228a is formed at a distance (d₄) from the n+-doped silicon slab region 116.

In accordance with the embodiments of FIG. 3, Δx refers to the distance between the left edge of the horizontal portion of the second FP 228a and the p-n junction 118.

The horizontal portion of the first FP 226a and the horizontal portion of the second FP 228a define a horizontal gap (g) therebetween. The horizontal gap (g) can be configured such that the electric field suppression achieved along the interface between the n+-doped region 116 and the top cladding layer 104 is not disturbed while maintaining a high-enough electric field suppression along the interface between the p-doped silicon slab region 114 and the top cladding layer 104 interface.

### WORKING EXAMPLES

A series of Technology Computer-Aided Design (TCAD) simulations were conducted in order to model embodiments of the SPADs disclosed herein with variations in their device geometry and doping configuration. In particular, an optimization study was performed to suppress the electric field strength along the oxide interfaces by changing the distance Δx between the p-n junction and the left edge of the FP located in the RHS of the device. In the following simulation results, the distance Δx is 0 nm.

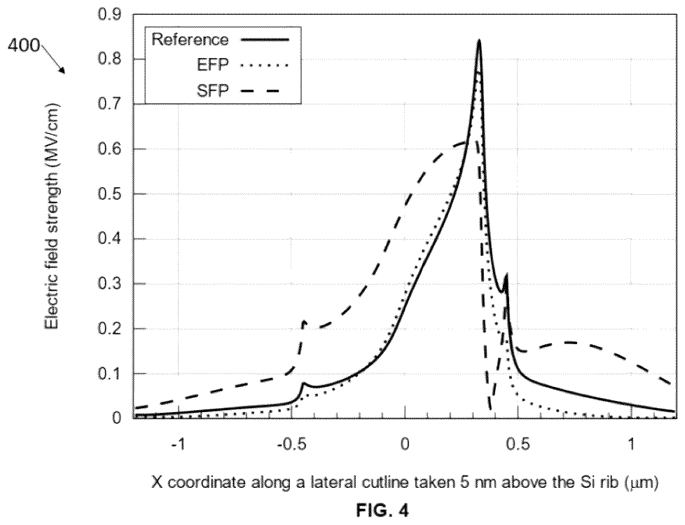

FIG. 4 illustrates a graph 400 between the X coordinate at 5 nm above the rib waveguide and an electric field associated with the waveguide-based SPAD of prior art (Ref), the waveguide-based SPAD 100 (SFP), and the waveguide-based SPAD 200 (EFP), in accordance with an aspect of the present disclosure. As shown, the design with EFP suppresses the peak field at top cladding without extending the high-field oxide interface, and the design with SFP provides better field suppression at the expense of slightly widened high-field oxide interface.

In particular, FIG. 4 shows the electric field profile along a lateral cutline taken 5 nm above the top of the silicon rib waveguide such that it illustrates the electric field strength along the Si SPAD/top oxide interface. The x-axis of the graph denotes the position along that cutline; the x=0 μm corresponds to the center of the rib waveguide. The y-axis denotes the electric field strength in units of Megavolt (MV) per cm. FIG. 4 clearly shows that the SFP and EFP designs suppress the electric field strength along the top oxide interface compared to the reference device.

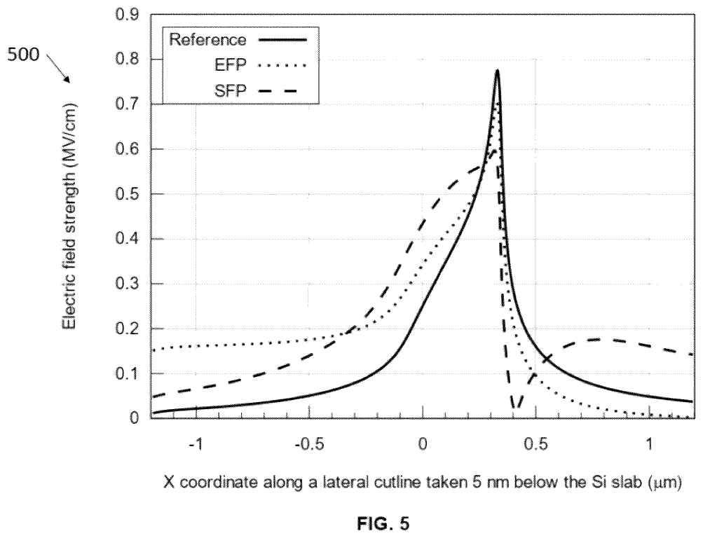

FIG. 5 illustrates a graph 500 between the X coordinate at 5 nm below the rib waveguide and an electric field associated with the waveguide-based SPAD of prior art (Ref), the waveguide-based SPAD 100 (SFP), and the waveguide-based SPAD 200 (EFP), in accordance with an aspect of the present disclosure. As shown, the EFP design with a grounded substrate reduces the electric field along the bottom oxide surface, whereby the maximum electric field no longer locates at the oxide interface but inside the depletion region. Further, the SFP performs better in suppressing the peak field strength, albeit at a cost of additional electrode formation and bias condition.

In particular, FIG. 5 shows the electric field profile along a cutline taken 5 nm below the bottom of the silicon rib waveguide such that it illustrates the electric field strength along the Si SPAD/bottom oxide interface. The x-axis of the graph denotes the position along that cutline; the x=0 μm corresponds to the center of the rib waveguide. The y-axis denotes the electric field strength in units of MV per cm. FIG. 5 clearly shows that the SFP and EFP designs suppress the peak electric field strength along the bottom oxide interface compared to the reference device.

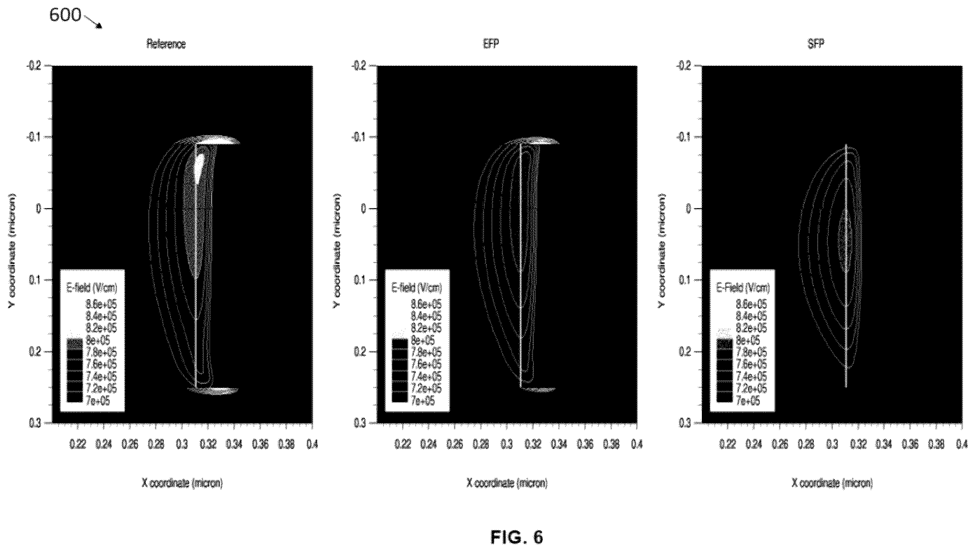

FIG. 6 illustrates simulated electric field profiles 600 in accordance with embodiments and configurations of the present disclosure. The graphs show that the SFP and EFP designs suppress the electric field localized along the oxide interface, and hence, allow for preventing premature surface breakdown of the devices.

In particular, FIG. 6 shows the TCAD simulations of the cross-sectional profile of the electric field strength near the multiplication region. Here, the devices are modelled with their device structure and doping profiles. A bias voltage near the breakdown voltage of the corresponding devices is applied across the electrodes, and the resulting electric field profiles are plotted as a 2D contour plot. Here, the whole cross-section of the device including the electrodes and the entire rib waveguide have been simulated; however, only the multiplication regions are shown to better illustrate the effect. FIG. 6 clearly shows that the highest electric field strength at the top and bottom oxide interface occurs in the reference device. However, SFP and EFP designs suppress the electric field towards the rib waveguide core and result in more uniform distribution of the electric field lines inside the waveguide core; therefore, more homogeneous multiplication region is achieved.

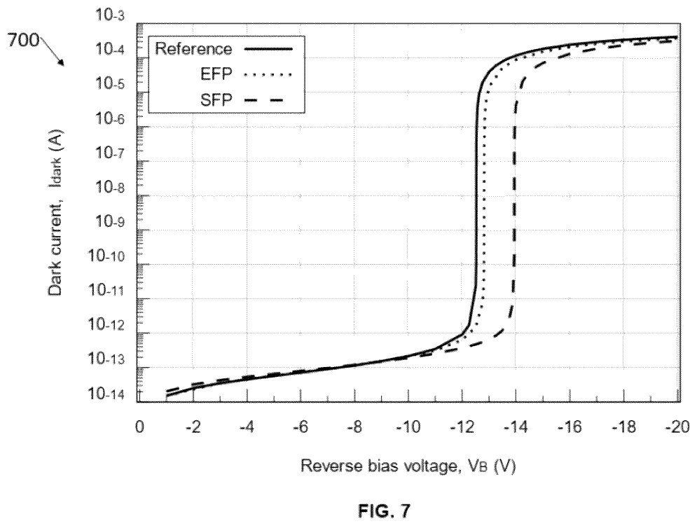

FIG. 7 illustrates a graph 700 for the simulated dark-current vs. reverse bias voltage for the waveguide-based SPAD of the prior art (Ref), the waveguide-based SPAD of FIG. 2 (SFPs) and FIG. 3 (EFPs), in accordance with an aspect of the present disclosure. As shown in FIG. 7, the use of field plates compared to the reference device results in avalanche breakdown of the device at higher bias voltages due to suppression of the electric field along the oxide interface.

It will be appreciated that variations of the above disclosed and other features and functions, or alternatives thereof, may be desirably combined into many other different systems or applications. Also, various presently unforeseen or unanticipated alternatives, modifications, variations, or improvements therein may be subsequently made by those skilled in the art which are also intended to be encompassed by the following claims.

Although embodiments of the current disclosure have been described comprehensively in considerable detail to cover the possible aspects, those skilled in the art would recognize that other versions of the disclosure are also possible.

1. A single photon avalanche diode (SPAD) comprising:
a rib waveguide with a doping profile comprising a multiplication junction;
a top cladding layer disposed on a top surface of the rib waveguide;
a bottom cladding layer disposed on a bottom surface of the rib waveguide;
an anode;
a cathode; and
at least two field plates,
wherein the anode, cathode and at least two field plates are configured to suppress an electric field over the multiplication junction relative to the SPAD without the at least two field plates,
wherein the at least two field plates are positioned adjacent to an intersection of the multiplication junction.

2. The single photon avalanche diode of claim 1, wherein the doping profile is selected from:
p+/i/p/n+;
p++/p/i/n+/n++; and
p++/p/n+/n++.

3. The single photon avalanche diode of claim 2, wherein the multiplication junction is i/n+ or p/n+.

4. The single photon avalanche diode of any one of claims 1-3, wherein the multiplication junction forms a multiplication region when an appropriate bias voltage is applied between the anode and cathode.

5. The single photon avalanche diode of claim 1, wherein the diode is reverse-biased slightly beyond an avalanche breakdown voltage of the diode to achieve Geiger-mode operation, wherein the anode is kept at lower electric potential than the cathode, wherein the cathode is electrically grounded.

6. The single photon avalanche diode of claim 1, wherein the at least two field plates comprise a first field plate and a second field plate that sandwich the rib waveguide adjacent to the multiplication junction, and they are voltage biased.

7. The single photon avalanche diode of claim 6,
wherein the anode is disposed at a first end of the rib waveguide and extends vertically to form an anode pillar,
wherein the cathode is disposed at a second end of the rib waveguide and extends vertically to form a cathode pillar,
wherein the first field plate and the second field plate that are positioned adjacent to the multiplication junction,
wherein the first field plate is formed in the top cladding layer, and
wherein the second field plate is formed in the bottom cladding layer.

8. The single photon avalanche diode of claim 7, wherein the first field plate is asymmetrically positioned between the anode pillar and the cathode pillar, and it is voltage biased.

9. The single photon avalanche diode of claim 6, wherein the doping profile of the rib waveguide is p++/p/n+/n++ and the multiplication junction is p/n+, wherein the first field plate is horizontally displaced from the p-n junction by a distance Δx over the n+ doped region and vertically displaced from the n+ doped region by a distance d₁,
wherein the second field plate is in vertical alignment with the first field plate and is horizontally displaced from the p-n junction by a distance Δx underneath the n+ doped region and vertically displaced from the n+ doped region by a distance d₂.

10. The single photon avalanche diode of claim 6, wherein a potential difference of V_{B} with respect to an electrical ground is applied to the first field plate and the second field plate to suppress an electrostatic potential gradient in a y-axis (i.e., E_{y}) along an interface between the multiplication junction and the top cladding layer to improve a resilience of the diode to premature surface breakdown.

11. The single photon avalanche diode of claim 1, wherein the at least two field plates comprise a first field plate and a second field plate,
wherein the first field plate with the anode forms an L-shaped extended anode and the second field plate with the cathode forms an L-shaped extended cathode both of which extend towards the multiplication junction through the top cladding layer,
wherein the L-shaped extended anode and L-shaped extended cathode suppress an electrostatic potential gradient along a y-axis (i.e., E_{y}) along an interface between the multiplication junction and the top cladding layer to improve a resilience of the diode to premature surface breakdown.

12. The single photon avalanche diode of claim 11,
wherein the first field plate laterally extends towards the multiplication junction in a second metal layer of the top cladding layer,
wherein the second field plate laterally extends towards the multiplication junction in a first metal layer of the top cladding layer.

13. The single photon avalanche diode of claim 11, wherein the first field plate and the second field plate are horizontally separated by a gap g.

14. The single photon avalanche diode of claim 12, wherein the second field plate laterally extends towards the multiplication junction in the first metal layer of the top cladding layer with a distance Δx in between.

15. The single photon avalanche diode of claim 14, wherein the doping profile of the rib waveguide is p++/p/n+/n++ and the multiplication junction is p/n+,
wherein the second field plate extends from the n++ doped region to the n+ doped region and is vertically displaced from the n+ doped region by a distance d₄,
wherein the first field plate is horizontally displaced from the second field plate by a gap g and is vertically displaced from the p doped region by a distance d₃.

16. The single photon avalanche diode of claim 15, wherein the first field plate is extended in the second metal layer of the top cladding layer to prevent disturbance of the field suppression over the n+ doped region by the second field plate and to avoid dielectric breakdown between the field plates while maintaining adequate electric field suppression along the intersection of the p doped region and the top cladding layer.
